(19) United States
(12) Patent Application Publication
(10) Pub. No.: US 2020/0161401 A1
(43) Pub. Date: May 21, 2020

(54) DISPLAY SUBSTRATE, METHOD FOR PREPARING THE SAME, AND DISPLAY DEVICE

(71) Applicants: HEFEI XINSHENG OPTOELECTRONICS TECHNOLOGY CO., LTD., Hefei (CN); BOE TECHNOLOGY GROUP CO., LTD., Beijing (CN)

(72) Inventor: Ning LIU, Beijing (CN)

(73) Assignees: HEFEI XINSHENG OPTOELECTRONICS TECHNOLOGY CO., LTD., Hefei, Anhui (CN); BOE TECHNOLOGY GROUP CO., LTD., Beijing (CN)

(21) Appl. No.: 16/560,281

(22) Filed: Sep. 4, 2019

(30) Foreign Application Priority Data
Nov. 19, 2018 (CN) 201811375295.5

(51) Int. Cl. H01L 27/32

(52) U.S. Cl. CPC H01L 27/3272; H01L 2227/323

(57) ABSTRACT

The present disclosure relates to a display substrate, a method for preparing the same and a display device. The display substrate includes an active layer on a substrate and a light-shielding metal layer between the substrate and the active layer, in which an orthogonal projection of the active layer on the substrate falls into an orthogonal projection of the light-shielding metal layer on the substrate, a first thermal-insulation insulating layer is arranged between the active layer and the light-shielding metal layer, and a second thermal-insulation insulating layer is arranged on a side of the active layer away from the light-shielding metal layer.

### CROSS-REFERENCE TO RELATED APPLICATION

This application claims priority to Chinese Patent Application No. 201811375295.5 filed on Nov. 19, 2018, which is incorporated herein by reference in its entirety.

### TECHNICAL FIELD

The present disclosure relates to the field of display, in particular, to a display substrate, a method for preparing the same and a display device.

### BACKGROUND

The top-gate type thin film transistor (TFT) has the characteristics of a short channel, so that its on-state current Iₒₙ can be effectively improved, thereby significantly improving the display effect and effectively reducing power consumption. Moreover, since the top-gate type TFT has a small overlap area between the gate electrode and the source and drain electrodes, the generated parasitic capacitance is small, and the possibility of occurrence of defects such as short-circuiting of the gate and the drain is also reduced. Since the top-gate type thin film transistor has the above-mentioned remarkable advantages, it is getting more and more attention.

In order to prevent the influence of external light on the active layer of the top-gate type thin film transistor, a light-shielding metal layer is usually arranged directly under the active layer. However, when other film layers are formed on the active layer, a high temperature deposition and an annealing are usually employed. Since the heat transfer efficiency of the light-shielding metal layer is relatively high, heat is rapidly transferred to the active layer. If the active layer is made from a metal oxide material, after the active layer is heated, the oxygen therein is easily diffused, resulting in a negative drift of the turn-on voltage of the thin film transistor. The voltage after negative drift is −5V to −1V.

In the circuit design of Active Matrix Organic Light Emitting Diode (AMOLED) products, the 3T1C structure is often employed. The driving thin film transistor is provided with a light-shielding metal layer, so that it is more likely to occur a negative drift of the turn-on voltage than the switching thin film transistor and the compensation thin film transistor, resulting in the adjustment direction of the turn-on voltage of each thin film transistor in the display panel to be not synchronized, thereby affecting the display quality.

### SUMMARY

The present disclosure provides a display substrate, including an active layer on a substrate and a light-shielding metal layer between the substrate and the active layer, in which an orthogonal projection of the active layer on the substrate falls into an orthogonal projection of the light-shielding metal layer on the substrate, a first thermal-insulation insulating layer is arranged between the active layer and the light-shielding metal layer, and a second thermal-insulation insulating layer is arranged on a side of the active layer away from the light-shielding metal layer.

Optionally, the first thermal-insulation insulating layer and the second thermal-insulation insulating layer are in direct contact with the active layer.

Optionally, the display substrate further includes a channel in the active layer, and a buffer layer arranged between the active layer and the light-shielding metal layer, as well as a gate insulating layer, a gate electrode, an interlayer dielectric layer, a source electrode and a drain electrode, which are sequentially arranged in a direction from the active layer to the source electrode and the drain electrode.

Optionally, the first thermal-insulation insulating layer and the second thermal-insulation insulating layer each have a thermal conductivity of less than 100 mW/mK.

Optionally, the first thermal-insulation insulating layer and the second thermal-insulation insulating layer are each made from a composite material of phenol resin and silicon dioxide.

Optionally, the first thermal-insulation insulating layer between the active layer and the light-shielding metal layer is reused as a buffer layer.

Optionally, the second thermal-insulation insulating layer on the side of the active layer away from the light-shielding metal layer is reused as a gate insulating layer.

Optionally, the buffer layer has a thickness of 3000 Å to 6000 Å.

Optionally, the gate insulating layer has a thickness of 1000 Å to 3000 Å.

Optionally, the display substrate further includes a non-metal passivation layer arranged over the source electrode and the drain electrode.

The present disclosure provides a method for preparing a display substrate, including: forming an active layer on a substrate and a light-shielding metal layer between the substrate and the active layer, wherein an orthogonal projection of the active layer on the substrate falls into an orthogonal projection of the light-shielding metal layer on the substrate; and the method further including: forming a first thermal-insulation insulating layer between the active layer and the light-shielding metal layer; and forming a second thermal-insulation insulating layer on a surface of the active layer away from the light-shielding metal layer.

Optionally, the method for preparing the display substrate further includes: forming a buffer layer on a surface of the light-shielding metal layer; and forming a gate insulating layer, a gate electrode, an interlayer dielectric layer, a source electrode and a drain electrode in sequence on a surface of the active layer, to obtain the display substrate.

Optionally, the method for preparing the display substrate includes: providing a substrate; forming a light-shielding metal layer on the substrate; forming a first thermal-insulation insulating layer reused as a buffer layer on a surface of the light-shielding metal layer; forming an active layer on the first thermal-insulation insulating layer reused as the buffer layer, in which an orthogonal projection of the active layer on the substrate falls into an orthogonal projection of the light-shielding metal layer on the substrate; forming a second thermal-insulation insulating layer reused as a gate insulating layer on a surface of the active layer; forming a gate electrode; forming an interlayer dielectric layer; and forming a source electrode and a drain electrode.

Optionally, the forming the first thermal-insulation insulating layer reused as the buffer layer on the surface of the light-shielding metal layer includes: forming the first thermal-insulation insulating layer reused as the buffer layer by spin coating or spraying a composite material of phenolic resin and silicon dioxide on the surface of the light-shielding metal layer, and drying the composite material; and the forming the second thermal-insulation insulating layer reused as the gate insulating layer on the surface of the active layer includes: forming the second thermal-insulation insulating layer reused as the gate insulating layer by spin coating or spraying a composite material of phenolic resin and silicon dioxide on the surface of the active layer, and drying the composite material.

Optionally, the drying is performed at a temperature of 100° C. to 200° C. for a period of 30 to 120 mins.

The present disclosure also provides a display device, including the display substrate of the above technical solutions.

### BRIEF DESCRIPTION OF THE DRAWINGS

FIG. 1 is a schematic view showing a display substrate according to an embodiment of the present disclosure.

FIG. 2 is a schematic view showing a display substrate according to another embodiment of the present disclosure.

FIG. 3 is a schematic view showing a display substrate according to a yet another embodiment of the present disclosure.

FIG. 4 is a circuit diagram showing a top-gate type AMOLED product.

### DETAILED DESCRIPTION

In order to better understand the present disclosure, the specific embodiments of the present disclosure will be described below in combination with Examples, but it should be understood that these descriptions are merely used to further illustrate the features and advantages of the present disclosure and are not intended to limit the present disclosure.

The embodiment of the present disclosure provides a display substrate, including an active layer on a substrate and a light-shielding metal layer between the substrate and the active layer, in which an orthogonal projection of the active layer on the substrate falls into an orthogonal projection of the light-shielding metal layer on the substrate, a first thermal-insulation insulating layer is arranged between the active layer and the light-shielding metal layer, and a second thermal-insulation insulating layer is arranged on a side of the active layer away from the light-shielding metal layer.

As for a display substrate provided with a light-shielding metal layer, the light-shielding metal layer has a high thermal conductivity, resulting in a change in the performance of the active layer after being heated. In particular, in the case that the active layer made from a metal oxide material is heated, the oxygen therein is easily diffused, resulting in a negative drift of the turn-on voltage.

In the present disclosure, a thermal-insulation insulating layer is arranged on both sides of the active layer. Specifically, a first thermal-insulation insulating layer is arranged between the active layer and the light-shielding metal layer, and a second thermal-insulation insulating layer is arranged on a side of the active layer away from the light-shielding metal layer.

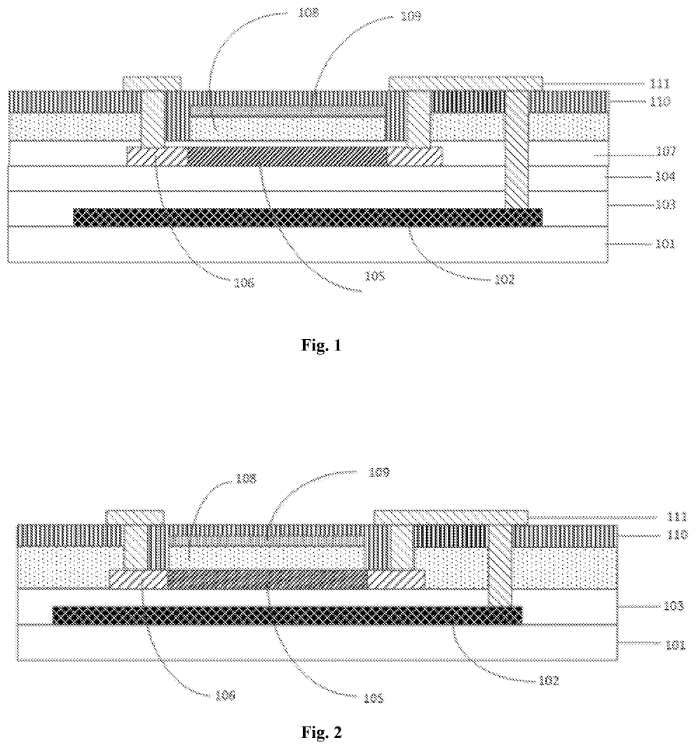

As shown in FIG. 1, the structure of the display substrate includes: a substrate 101, a light-shielding metal layer 102, a buffer layer 103, a first thermal-insulation insulating layer 104, an active layer 106, a channel 105 in the active layer, a second thermal-insulation insulating layer 107, a gate insulating layer 108, a gate electrode 109, a interlayer dielectric layer 110, and a source electrode 113 and a drain electrode 111, which are arranged in sequence.

Optionally, the first thermal-insulation insulating layer and the second thermal-insulation insulating layer each have a thermal conductivity of less than 100 mW/mK, and they may be made from the same material or different materials. Optionally, they are made from the same material. More optionally, the first thermal-insulation insulating layer and the second thermal-insulation insulating layer are each made from a composite material of phenol resin and silicon dioxide. The inventor screened the thermal-insulation insulating material suitable for display substrates through a large number of experiments, and found that the composite material of phenolic resin and silicon dioxide has an excellent thermal insulation property, and that the material itself does not adversely affect display substrates and has a very good compatibility to other layers of the display substrates. The composite material of the phenolic resin and the silicon dioxide is obtained by adding chitosan as a basic template, and adding phenol, formaldehyde and ethyl orthosilicate to perform a polymerization reaction. After the reaction is completed, a separation and a purification are performed by the column, and a composite insulating material of phenolic resin and silicon dioxide is obtained after drying. The phenolic resin nanofiber and the silicon dioxide nanofiber for the composite material of the phenolic resin and the silicon dioxide are entangled and overlapped with each other. Thus, it has a good physical toughness, and the structure thereof is stable. The lowest thermal conductivity can reach 24 mW/mK, and thus fire resistance thereof is good.

In order to simplify the preparation process, optionally, the first thermal-insulation insulating layer between the active layer and the light-shielding metal layer is reused as a buffer layer. The buffer layer is an insulating film layer between the light-shielding metal layer and the active layer, and functions to isolate the active layer from the light-shielding metal layer and to effectively block various metal ion impurities in the substrate from diffusing into the active layer. Optionally, the buffer layer has a thickness of 3000 Å to 6000 Å. The second thermal-insulation insulating layer on the side of the active layer away from the light-shielding metal layer is reused as a gate insulating layer. Optionally, the gate insulating layer has a thickness of 1000 Å to 3000 Å.

As shown in FIG. 2, the display substrate includes: a substrate 101, a light-shielding metal layer 102, a buffer layer 103, an active layer 106, a channel 105 in the active layer, a gate insulating layer 108, a gate electrode 109, an interlayer dielectric layer 110, and a source electrode 113 and a drain electrode 111 arranged in sequence.

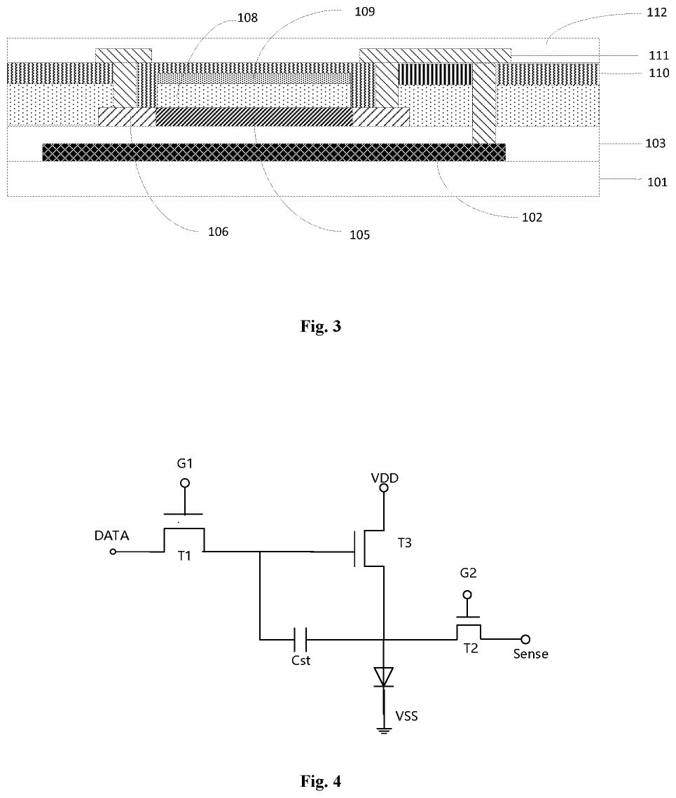

As shown in FIG. 3, the display substrate may further include a non-metal passivation layer 112.

As compared with the prior art, the present disclosure provides a thermal-insulation insulating layer on both sides of the active layer of the display substrate, in which the thermal-insulation insulating may better insulate heat conduction, thereby avoiding a negative drift of the turn-on voltage due to the active layer being heated. Further, when the 3T1C structure is included in the AMOLED circuit, the thermal-insulation insulating layer is arranged on both sides of the active layer of the driving thin film transistor, a negative drift of the turn-on voltage due to the active layer being heated is avoided, thereby allowing a relatively high synchronization of the turn-on voltage between the driving the thin film transistor and the switching transistors and compensation transistors, thereby ensuring a better display quality.

The present disclosure further provides a method for preparing a display substrate, including: forming an active layer on a substrate and a light-shielding metal layer between the substrate and the active layer, wherein an orthogonal projection of the active layer on the substrate falls into an orthogonal projection of the light-shielding metal layer on the substrate; and the method further including: forming a first thermal-insulation insulating layer between the active layer and the light-shielding metal layer; forming an active layer on a surface of the first thermal-insulation insulating layer; and forming a second thermal-insulation insulating layer on a surface of the active layer.

Specifically, the forming the first thermal-insulation insulating layer between the active layer and the light-shielding metal layer is conducted by dissolving the thermal-insulation insulating material into an organic solvent, spin coating or spraying the resulting solution on the surface of the light-shielding metal layer, and drying it.

The forming a second thermal-insulation insulating layer on the surface of the active layer is conducted by dissolving the thermal-insulation insulating material in an organic solvent, spin coating or spraying the resulting solution on the surface of the active layer, and drying it.

Optionally, in the case that the first thermal-insulation insulating layer is reused as a buffer layer and the second thermal-insulation insulating layer is reused as a gate insulating layer, the method for preparing the display substrate may include:

S1: providing a substrate.

S2: forming a light-shielding metal layer on the substrate.

S3: forming a first thermal-insulation insulating layer reused as a buffer layer on a surface of the light-shielding metal layer.

Optionally, the first thermal-insulation insulating layer has a thermal conductivity of less than 100 mW/mK. Optionally, the first thermal-insulation insulating layer is made from a composite material of phenolic resin and silicon dioxide.

The step S3 specifically includes: forming the first thermal-insulation insulating layer reused as the buffer layer by spin coating or spraying a composite material of phenolic resin and silicon dioxide on the surface of the light-shielding metal layer, and drying the composite material.

If a spraying is used, a linear spraying may be employed, in which the moving speed of the nozzle is about 100 to 300 mm/s.

Optionally, the drying is performed at a temperature of 100° C. to 200° C., and optionally, the drying is performed for a period of 30 to 120 mins.

S4: forming an active layer on the first thermal-insulation insulating layer reused as the buffer layer, in which an orthogonal projection of the active layer on the substrate falls into an orthogonal projection of the light-shielding metal layer on the substrate.

S5: forming a second thermal-insulation insulating layer reused as a gate insulating layer on a surface of the active layer.

Optionally, the second thermal-insulation insulating layer has a thermal conductivity of less than 100 mW/mK. Optionally, the second thermal-insulation insulating layer is made from a composite material of phenolic resin and silicon dioxide.

The step S5 is: forming the second thermal-insulation insulating layer reused as the gate insulating layer by spin coating or spraying a composite material of phenolic resin and silicon dioxide on the surface of the active layer, and drying the composite material.

Among them, if a spraying is used, a linear spraying may be employed, in which the moving speed of the nozzle is about 100 mm/s to 300 mm/s. Optionally, the drying is performed at a temperature of 100° C. to 200° C., and optionally, the drying is performed for a period of 30 to 120 mins.

S6: forming a gate electrode and forming an interlayer dielectric layer.

S7: forming a source electrode and a drain electrode, to obtain the display substrate.

Since the first thermal-insulation insulating layer and the second thermal-insulation insulating layer made from the composite material of the phenolic resin and the silicon dioxide can be etched by the plasma gases CF₄ and O₂, which are commonly used in the dry etching process, various vias such as interlayer dielectric layer (ILD) holes, connection (CNT) holes, and vias can be formed smoothly for various subsequent metal lappings, thereby forming a complete TFT preparing process. The use of the novel insulating material can significantly improve the characteristic stability of the display substrate, thereby improving the display quality of the display panel.

When the 3T1C structure is employed in the circuit design of the display substrate, as shown in FIG. 4, when there are three thin film transistors and one capacitor, the thin film transistor of the display substrate described in the above aspects is optionally configured to the driving thin film transistor. In FIG. 4, DATA is a data line; G1 is a first scan line; G2 is a second scan line; VDD is a drain electrode of a power supply voltage; VSS is a source electrode of a power supply voltage; sense is a compensation line; T1, T2, and T3 are thin film transistors; and Cst is a capacitor. In order to simplify the overall preparing process of the display substrate, the active layer of the switching thin film transistor and the active layer of the compensation thin film transistor are each made from a thermal-insulation insulating material. Optionally, the thermal-insulation insulating material has a thermal conductivity of less than 100 mW/mK.

When the first thermal-insulation insulating layer of the driving thin film transistor of the display substrate is reused as the buffer layer and the second thermal-insulation insulating layer is reused as the gate insulating layer, the film layers on both sides of the switching thin film transistor are also reused as the buffer layer and the gate insulating layer respectively, and the film layers on both sides of the compensation thin film transistor are also reused as the buffer layer and the gate insulating layer respectively.

An embodiment of the present disclosure also discloses a display device, including the display substrate of the above technical solutions.

The above display device of the present disclosure was tested, and the experimental results show that the turn-on voltage of the thin film transistor of the display substrate improved by the present disclosure is around 0 V, and thus there is no negative drift.

The description of the above Examples is merely used for helping to understand the method according to the present disclosure and its core idea. It should be noted that a person skilled in the art may make further improvements and modifications to the disclosure without departing from the principle of the present disclosure, and these improvements and modifications shall also fall within the scope of the present disclosure.

The above description of the disclosed Examples allows one skilled in the art to implement or use the present disclosure. Various modifications to these Examples would be apparent to one skilled in the art, and the general principles defined herein may be applied to other Examples without departing from the spirit or scope of the disclosure. Therefore, the present disclosure will not be limited to the Examples shown herein, but should conform to the widest scope consistent with the principles and novel features disclosed herein.

What is claimed is:

1. A display substrate, comprising an active layer on a substrate and a light-shielding metal layer between the substrate and the active layer, wherein an orthogonal projection of the active layer on the substrate falls into an orthogonal projection of the light-shielding metal layer on the substrate, a first thermal-insulation insulating layer is arranged between the active layer and the light-shielding metal layer, and a second thermal-insulation insulating layer is arranged on a side of the active layer away from the light-shielding metal layer.

2. The display substrate of claim 1, wherein the first thermal-insulation insulating layer and the second thermal-insulation insulating layer are in direct contact with the active layer.

3. The display substrate of claim 1, further comprising a channel in the active layer, and a buffer layer arranged between the active layer and the light-shielding metal layer, as well as a gate insulating layer, a gate electrode, an interlayer dielectric layer, a source electrode and a drain electrode which are sequentially arranged in a direction from the active layer to the source electrode and the drain electrode.

4. The display substrate of claim 1, wherein the first thermal-insulation insulating layer and the second thermal-insulation insulating layer each have a thermal conductivity of less than 100 mW/mK.

5. The display substrate of claim 1, wherein the first thermal-insulation insulating layer and the second thermal-insulation insulating layer are each made from a composite material of phenol resin and silicon dioxide.

6. The display substrate of claim 1, wherein the first thermal-insulation insulating layer between the active layer and the light-shielding metal layer is reused as a buffer layer.

7. The display substrate of claim 1, wherein the second thermal-insulation insulating layer on the side of the active layer away from the light-shielding metal layer is reused as a gate insulating layer.

8. The display substrate of claim 6, wherein the buffer layer has a thickness of 3000 Å to 6000 Å.

9. The display substrate of claim 7, wherein the gate insulating layer has a thickness of 1000 Å to 3000 Å.

10. The display substrate of claim 1, further comprising a non-metal passivation layer arranged over the source electrode and the drain electrode.

11. A method for preparing a display substrate, comprising: forming an active layer on a substrate and a light-shielding metal layer between the substrate and the active layer, wherein an orthogonal projection of the active layer on the substrate falls into an orthogonal projection of the light-shielding metal layer on the substrate; and the method further comprising:
forming a first thermal-insulation insulating layer between the active layer and the light-shielding metal layer; and
forming a second thermal-insulation insulating layer on a surface of the active layer away from the light-shielding metal layer.

12. The method of claim 11, further comprising:
forming a buffer layer on a surface of the light-shielding metal layer; and
forming a gate insulating layer, a gate electrode, an interlayer dielectric layer, a source electrode and a drain electrode in sequence on a surface of the active layer.

13. The method of claim 11, wherein the method comprises:
providing a substrate;
forming a light-shielding metal layer on the substrate;
forming a first thermal-insulation insulating layer reused as a buffer layer on a surface of the light-shielding metal layer;
forming an active layer on the first thermal-insulation insulating layer reused as the buffer layer, wherein an orthogonal projection of the active layer on the substrate falls into an orthogonal projection of the light-shielding metal layer on the substrate;
forming a second thermal-insulation insulating layer reused as a gate insulating layer on a surface of the active layer;
forming a gate electrode;
forming an interlayer dielectric layer; and
forming a source electrode and a drain electrode.

14. The method of claim 12, wherein the forming the first thermal-insulation insulating layer reused as the buffer layer on the surface of the light-shielding metal layer comprises:
forming the first thermal-insulation insulating layer reused as the buffer layer by spin coating or spraying a composite material of phenolic resin and silicon dioxide on the surface of the light-shielding metal layer, and drying the composite material; and
the forming the second thermal-insulation insulating layer reused as the gate insulating layer on the surface of the active layer comprises: forming the second thermal-insulation insulating layer reused as the gate insulating layer by spin coating or spraying a composite material of phenolic resin and silicon dioxide on the surface of the active layer, and drying the composite material.

15. The method of claim 14, wherein the drying is performed at a temperature of 100° C. to 200° C. for a period of 30 to 120 mins.

16. The method of claim 11, wherein the first thermal-insulation insulating layer and the second thermal-insulation insulating layer each have a thermal conductivity of less than 100 mW/mK.

17. The method of claim 13, wherein the buffer layer has a thickness of 3000 to 6000 Å.

18. The method of claim 13, wherein the gate insulating layer has a thickness of 1000 to 3000 Å.

19. A display device, comprising the display substrate of claim 1.
